(19) United States
(12) Patent Application Publication
(10) Pub. No.: US 2007/0152711 A1
(43) Pub. Date: Jul. 5, 2007

(54) LEVEL SHIFTER OUTPUT BUFFER CIRCUIT USABLE AS AN ISOLATION CELL

(76) Inventors: Mun Weon Ahn, Seoul (KR); Il Hae Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/617,410

(22) Filed: Dec. 28, 2006

(30) Foreign Application Priority Data
Dec. 29, 2005 (KR) 10-2005-0133514

(51) Int. Cl. H03K 19/0175

(52) U.S. Cl. 326/81

(57) ABSTRACT

A level shifter output buffer circuit which converts a first operating voltage into a second operating voltage and outputs a converted voltage to an output terminal. A level shifter output buffer circuit may include at least one of: a first level shifter configured to receive an enable signal as an input having a first operating voltage; a second level shifter configured to receive a data signal as an input having a first operating voltage; a pull-up transistor configured to output a second operating voltage to an output terminal based on the output of a first level shifter and a second level shifter.

The present application claims priority under 35 U.S.C. 119 and 35 U.S.C. 365 to Korean Patent Application No. 10-2005-0133514 (filed on Dec. 29, 2005), which is hereby incorporated by reference in its entirety.

### BACKGROUND

An integrated circuit device (e.g. a system-on-chip (SoC)) may include both a memory device and a logic device on a single chip. A memory device and a logic device may have different operating voltage levels. A level shifter or level translator may shift the voltage level of output data from a first device (e.g. a memory device) into an operation voltage level of a second device (e.g. a logic device on the same chip as the memory device). A level shifter may allow two devices to have operating voltages based on a voltage conversion.

FIG. 1 illustrates low voltage operating device 12 having a first operating voltage (e.g. 1.2V) and high voltage operating device 14 having a second operating voltage (e.g. 1.5V). Low voltage operating device 12 and high voltage operating device 14 may have the same external power sources (e.g. V_{DDL} and V_{DDH}) and ground. If low voltage operating device 12 outputs data to high voltage operating device 14, a low voltage may be shifted to a high voltage using level shifter 10 (See ‘B’ of FIG. 1). If data is output from high voltage operating device 14 to low voltage operating device 12, high voltage data may be converted into low voltage data (See ‘A’ of FIG. 1). However, level shifter 10 may have the limitation that it can only shift the voltage level of output data.

### SUMMARY

Embodiments relate to a level shifter that may convert both data and isolation signals.

Embodiments relate to a level shifter output buffer circuit which converts a first operating voltage into a second operating voltage and outputs a converted voltage to an output terminal. A level shifter output buffer circuit may include at least one of: a first level shifter configured to receive an enable signal as an input having a first operating voltage; a second level shifter configured to receive a data signal as an input having a first operating voltage; a pull-up transistor configured to output a second operating voltage to an output terminal based on the output of a first level shifter and a second level shifter.

### BRIEF DESCRIPTION OF THE DRAWINGS

FIG. 1 illustrates a semiconductor integrated circuit device including a level shifter.

Example FIGS. 2 and illustrate block circuits including level shifter output buffer circuits, according to embodiments.

### DETAILED DESCRIPTION

Embodiments relate to a level shifter output buffer circuit. As illustrated in FIG. 2, level shifter output buffer circuit 100a may include two level shifters, in accordance with embodiments. In embodiments, level shifter output buffer circuit 100a may include first level shifter 22 and second level shifter 24. First level shifter 22 may be configured to receive an enable signal EN as an input. Second level shifter 24 may be configured to receive a data signal DATA as an input.

Level shifter output buffer circuit 100a may shift enable signal EN and data signal DATA from a high voltage level (e.g. 1.5V) to a low voltage level (e.g. 1.2V). Circuit 100a may include NAND gate 26, in accordance with embodiments. NAND gate 26 may be configured to receive outputs from both first level shifter 22 and second level shifter 24. An output of NAND gate 26 may be connected to pull-up transistor 28. Level shifter output buffer circuit 100a may include first NOR gate 30, in accordance with embodiments. First NOR gate 30 may be configured to receive outputs of first level shifter 22 and second level 24. An output of first NOR gate 30 may be input into inverter 32. An output of inverter 32 may be input into second NOR gate 34. An output of second NOR gate 34 may be input into pull-down transistor 36.

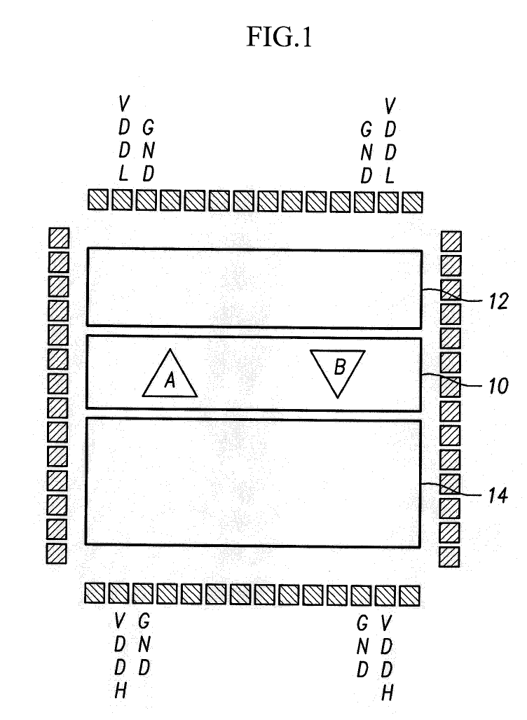

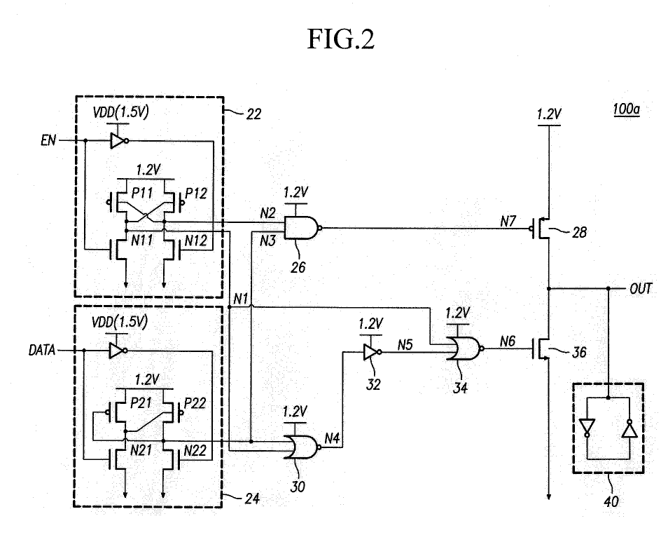

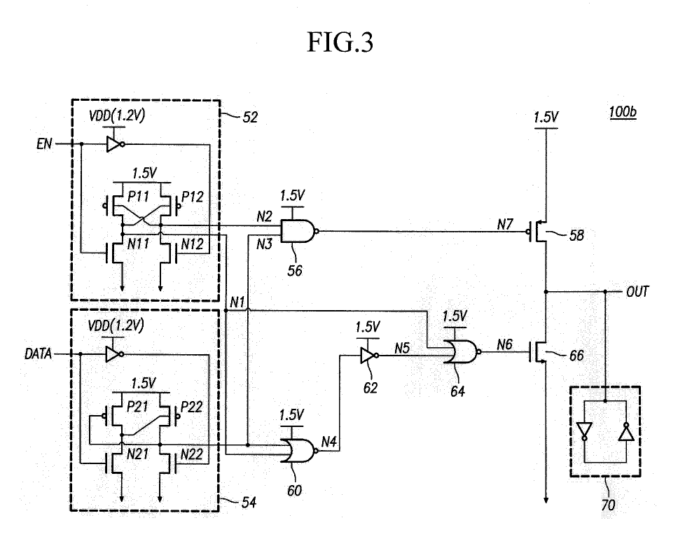

In embodiments, a buffer circuit may shift enable and data signals from a high voltage (e.g. 1.5V) to a low voltage (e.g. 1.2V) to output voltage shifted enable and data signals. In embodiments, level shifter output buffer circuit 100a may be included in a high voltage operating device (e.g. high voltage operating device 14 of FIG. 1). Circuit 100a may convert data signal DATA and/or enable signal EN from a high voltage range (e.g. 0V to 1.5V) to a low voltage range (e.g. 0V to 1.2V). In a high voltage data signal, 1.5V may represent a logical “1” and 0V (i.e. ground) may represent a logical “0”. In a low voltage data signal, 1.2V may represent a logical “1” and 0V (i.e. ground) may represent a logical “0”.

Table 1 illustrates the inputs, outputs, and intermediate nodes of circuit 100a illustrated in FIG. 2.

TABLE 1

| EN | DATA | N1 | N2 | N3 | N4 | N5 | N6 | N7 | OUT |
|---|---|---|---|---|---|---|---|---|---|
| 1.5 V | 0 V | 0 V | 1.2 V | 0 V | 1.2 V | 0 V | 1.2 V | 1.2 V | 0 V |
| 1.5 V | 1.5 V | 0 V | 1.2 V | 1.2 V | 0 V | 1.2 V | 0 V | 0 V | 1.2 V |
| 0 V | 0 V | 1.2 V | 0 V | 0 V | 0 V | 1.2 V | 0 V | 1.2 V | Previously |
| | | | | | | | | | Latched |
| | | | | | | | | | Value |
| 0 V | 1.5 V | 1.2 V | 0 V | 1.2 V | 0 V | 1.2 V | 0 V | 1.2 V | Previously |
| | | | | | | | | | Latched |
| | | | | | | | | | Value |

For circuit 100a, when enable signal EN is 1.5V, 1.5V may be input into an inverter of first level shifter 22 and the inverter may output 0V to the gate of NMOS transistor N12 (i.e. turning NMOS transistor N12 off). When enable signal EN is 1.5V, 1.5V may be input into the gate of NMOS transistor N11 (i.e. turning NMOS transistor N11 on). When NMOS transistor N11 is turned on, the drain of NMOS transistor N11 is effectively connected to ground (i.e. 0V). Since node N1 is connected to the drain of transistor N11, node N1 will be at 0V when enable signal EN is at 1.5V.

The drain of NMOS transistor N11 may be connected to the gate of PMOS transistor P12 and the drain of NMOS transistor N12 may be connected to the gate of PMOS transistor P11. The source of PMOS transistor P11 may be connected to the drain of NMOS transistor N11 and the source of PMOS transistor P12 may be connected to the drain of NMOS transistor N12. The drain of PMOS transistor P11 and the drain of PMOS transistor P12 may be connected to a 1.2V voltage source. The drain of NMOS transistor N12 and the source of PMOS transistor P12 may be connected to node N2. When an enable signal EN is at 1.5V, node N2 is effectively connected a 1.2V voltage source, node N2 may be 1.2V. When an enable signal EN is at 0V, node N1 may be effectively connected to a 1.2V voltage source and node N2 may be effectively connected to ground (i.e. 0V).

When data signal DATA is 1.5V, 1.5V may be input into an inverter of second level shifter 24 and the inverter may output 0V to the gate of NMOS transistor N22 (i.e. turning NMOS transistor N22 off). When data signal DATA is 1.5V, 1.5V may be input into the gate of NMOS transistor N21 (i.e. turning NMOS transistor N21 on). When NMOS transistor N21 is turned on, the drain of NMOS transistor N21 is effectively connected to ground (i.e. 0V).

The drain of NMOS transistor N21 may be connected to the gate of PMOS transistor P22 and the drain of NMOS transistor N22 may be connected to the gate of PMOS transistor P21. The source of PMOS transistor P21 may be connected to the drain of NMOS transistor N21 and the source of PMOS transistor P22 may be connected to the drain of NMOS transistor N22. The drain of PMOS transistor P21 and the drain of PMOS transistor P22 may be connected to a 1.2V voltage source. The drain of NMOS transistor N22 and the source of PMOS transistor P22 may be connected to node N3. When a data signal DATA is at 1.5V, node N3 is effectively connected a 1.2V voltage source, node N3 may be 1.2V. When a data signal DATA is at 0V, node N3 may be effectively connected to ground (i.e. 0V).

Node N2 and node N3 may be input into NAND gate 26. The output of NAND gate 26 (node N7) may be input into the gate of PMOS transistor 28 (e.g. a pull-up transistor). Node N1 and node N3 may be input into NOR gate 30. The output of NOR gate 30 may be input into inverter 32. Node N1 and the output of inverter 32 may be input into NOR gate 34. The output of NOR gate 34 (node N6) may be input into the gate of NMOS transistor 36 (e.g. pull-down transistor).

When enable signal is at 0V, transistor 28 and transistor 36 will both be off, as node N7 will be 1.2V and node N6 will be 0V. If transistor 28 and transistor 36 are both off, then output OUT will not be influenced by data signal DATA. If transistor 28 and transistor 36 are both off, output OUT will isolated from the 1.2V source connected to the drain of transistor 28 and from ground (i.e. 0V) connected to the source of transistor 36. When enable signal EN is 0V, output OUT will be determined from latch gate 40. Latch gate 40 may latch the last output, which was output from output OUT.

As illustrated in FIG. 3, level shifter output buffer circuit 100b may include two level shifters, in accordance with embodiments. In embodiments, level shifter output buffer circuit 100b may include first level shifter 52 and second level shifter 54. First level shifter 52 may be configured to receive an enable signal EN as an input. Second level shifter 54 may be configured to receive a data signal DATA as an input.

Level shifter output buffer circuit 100b may shift enable signal EN and data signal DATA from a low voltage level (e.g. 1.2V) to a high voltage level (e.g. 1.5V). Circuit 100b may include NAND gate 56, in accordance with embodiments. NAND gate 56 may be configured to receive outputs from both first level shifter 52 and second level shifter 54. An output of NAND gate 56 may be connected to pull-up transistor 58. Level shifter output buffer circuit 100b may include first NOR gate 60, in accordance with embodiments. First NOR gate 60 may be configured to receive outputs of first level shifter 52 and second level 54. An output of first NOR gate 60 may be input into inverter 62. An output of inverter 62 may be input into second NOR gate 64. An output of second NOR gate 64 may be input into pull-down transistor 66.

In embodiments, a buffer circuit may shift enable and data signals from a low voltage (e.g. 1.2V) to a high voltage (e.g. 1.5V) to output voltage shifted enable and data signals. In embodiments, level shifter output buffer circuit 100b may be included in a low voltage operating device (e.g. low voltage operating device 12 of FIG. 1). Circuit 100b may convert data signal DATA and/or enable signal EN from a low voltage range (e.g. 0V to 1.2V) to a high voltage range (e.g. 0V to 1.5V). In a low voltage data signal, 1.2V may represent a logical “1” and 0V (i.e. ground) may represent a logical “0”. In a high voltage data signal, 1.5V may represent a logical “1” and 0V (i.e. ground) may represent a logical “0”.

Table 2 illustrates the inputs, outputs, and intermediate nodes of circuit 100b illustrated in FIG. 3.

TABLE 2

| EN | DATA | N1 | N2 | N3 | N4 | N5 | N6 | N7 | OUT |
|---|---|---|---|---|---|---|---|---|---|
| 1.2 V | 0 V | 0 V | 1.5 V | 0 V | 1.5 V | 0 V | 1.5 V | 1.5 V | 0 V |
| 1.2 V | 1.2 V | 0 V | 1.5 V | 1.5 V | 0 V | 1.5 V | 0 V | 0 V | 1.5 V |
| 0 V | 0 V | 1.5 V | 0 V | 0 V | 0 V | 1.5 V | 0 V | 1.5 V | Previously |
| | | | | | | | | | Latched |
| | | | | | | | | | Value |
| 0 V | 1.2 V | 1.5 V | 0 V | 1.5 V | 0 V | 1.5 V | 0 V | 1.5 V | Previously |
| | | | | | | | | | Latched |
| | | | | | | | | | Value |

For circuit 100b, when enable signal EN is 1.2V, 1.2V may be input into an inverter of first level shifter 52 and the inverter may output 0V to the gate of NMOS transistor N12 (i.e. turning NMOS transistor N12 off). When enable signal EN is 1.2V, 1.2V may be input into the gate of NMOS transistor N11 (i.e. turning NMOS transistor N11 on). When NMOS transistor N11 is turned on, the drain of NMOS transistor N11 is effectively connected to ground (i.e. 0V). Since node N1 is connected to the drain of transistor N11, node N1 will be at 0V when enable signal EN is at 1.2V.

The drain of NMOS transistor N11 may be connected to the gate of PMOS transistor P12 and the drain of NMOS transistor N12 may be connected to the gate of PMOS transistor P11. The source of PMOS transistor P11 may be connected to the drain of NMOS transistor N11 and the source of PMOS transistor P12 may be connected to the drain of NMOS transistor N12. The drain of PMOS transistor P11 and the drain of PMOS transistor P12 may be connected to a 1.5V voltage source. The drain of NMOS transistor N12 and the source of PMOS transistor P12 may be connected to node N2. When an enable signal EN is at 1.2V, node N2 is effectively connected a 1.5V voltage source, node N2 may be 1.5V. When an enable signal EN is at 0V, node N1 may be effectively connected to a 1.5V voltage source and node N2 may be effectively connected to ground (i.e. 0V).

When data signal DATA is 1.2V, 1.2V may be input into an inverter of second level shifter 54 and the inverter may output 0V to the gate of NMOS transistor N52 (i.e. turning NMOS transistor N22 off). When data signal DATA is 1.2V, 1.2V may be input into the gate of NMOS transistor N21 (i.e. turning NMOS transistor N21 on). When NMOS transistor N21 is turned on, the drain of NMOS transistor N21 is effectively connected to ground (i.e. 0V).

The drain of NMOS transistor N21 may be connected to the gate of PMOS transistor P22 and the drain of NMOS transistor N22 may be connected to the gate of PMOS transistor P21. The source of PMOS transistor P21 may be connected to the drain of NMOS transistor N21 and the source of PMOS transistor P22 may be connected to the drain of NMOS transistor N22. The drain of PMOS transistor P21 and the drain of PMOS transistor P22 may be connected to a 1.5V voltage source. The drain of NMOS transistor N22 and the source of PMOS transistor P22 may be connected to node N3. When a data signal DATA is at 1.2V, node N3 is effectively connected a 1.5V voltage source, node N3 may be 1.5V. When a data signal DATA is at 0V, node N3 may be effectively connected to ground (i.e. 0V).

Node N2 and node N3 may be input into NAND gate 56. The output of NAND gate 56 (node N7) may be input into the gate of PMOS transistor 58 (e.g. a pull-up transistor). Node N1 and node N3 may be input into NOR gate 60. The output of NOR gate 60 may be input into inverter 62. Node N1 and the output of inverter 62 may be input into NOR gate 64. The output of NOR gate 64 (node N6) may be input into the gate of NMOS transistor 66 (e.g. pull-down transistor).

When enable signal is at 0V, transistor 58 and transistor 56 will both be off, as node N7 will be 1.5V and node N6 will be 0V. If transistor 58 and transistor 66 are both off, then output OUT will not be influenced by data signal DATA. If transistor 58 and transistor 66 are both off, output OUT will isolated from the 1.5V source connected to the drain of transistor 58 and from ground (i.e. 0V) connected to the source of transistor 66. When enable signal EN is 0V, output OUT will be determined from latch gate 70. Latch gate 70 may latch the last output, which was output from output OUT.

One of ordinary skill in the art will appreciate that a low voltage range is not be limited to 0V to 1.2V and a high voltage range is not limited to 0V to 1.5V. One of ordinary skill in the art would appreciate other voltage ranges.

In embodiments, since a level shifter can shift the voltage of both an enable signal and a data signal, cells of a circuit may be isolated in a controlled manner. Controlled isolation of cells may allow for enhanced functions of a semiconductor device, in accordance with embodiments.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus comprising a level shifter output buffer, wherein the level shifter output buffer is configured to shift a first voltage level of a first signal and a second signal at substantially the same time to a second voltage level.

2. The apparatus of claim 1, wherein the first signal is a data signal.

3. The apparatus of claim 2, wherein the second signal is an enable signal.

4. The apparatus of claim 3, wherein the enable signal is applied at a logical “0”, then the output of the level shifter output buffer is electrically isolated.

5. The apparatus of claim 4, wherein:
the output of the level shifter is connected to a source of a pull-up transistor;
the drain of the pull-up transistor is connected to a voltage source having the second voltage level;
the output of the level shifter is connected to the drain of a pull-down transistor;
the source of the pull-down transistor is connected to ground; and
both the pull-up transistor and the pull-down transistor are in an off state when the enable signal is applied at a logical “0”.

6. The apparatus of claim 5, wherein the output is connected to a latch circuit, wherein the latch circuit maintains the previous output when both the pull-up transistor and the pull-down transistor are in an off state.

7. The apparatus of claim 5, wherein when the enable signal is applied at a logical “1” and the data signal is applied at a logical “1”, then the pull-up transistor is in an on state and the pull-down transistor is in an off state.

8. The apparatus of claim 5, wherein when the enable signal is applied at a logical “1” and the data signal is applied at a logical “0”, then the pull-up transistor is in an off state and the pull-down transistor is in an on state.

9. The apparatus of claim 1, wherein the level shifter output buffer is configured to convert the first signal of a first device having a first voltage level to the second signal of a second device having a second voltage level.

10. The apparatus of claim 9, wherein the level shifter output buffer is comprised in the first device.

11. The apparatus of claim 9, wherein the level shifter output buffer is comprised in the second device.

12. The apparatus of claim 9, wherein the first device and the second device are comprised on the same chip.

13. The apparatus of claim 1, wherein the level shifter output buffer is comprised in an integrated circuit device.

14. The apparatus of claim 13, wherein the integrated circuit device is a system-on-chip device.

15. The apparatus of claim 1, wherein the first voltage level is higher than the second voltage level.

16. The apparatus of claim 15, wherein:
the first voltage level is 1.5V; and
The second voltage level is 1.2V.

17. The apparatus of claim 1, wherein the first voltage level is lower than the second voltage level.

18. The apparatus of claim 17, wherein:
the first voltage level is 1.2V; and
The second voltage level is 1.5V.
